(19) United States
(12) Patent Application Publication
(10) Pub. No.: US 2004/0080051 A1
(43) Pub. Date: Apr. 29, 2004

(54) Semiconductor device

(75) Inventor: Kenji Kawai, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/667,519

(22) Filed: Sep. 23, 2003

(30) Foreign Application Priority Data
Oct. 29, 2002 (JP) 2002-314371(P)

(51) Int. Cl. H01L 23/48

(52) U.S. Cl. 257/758

(57) ABSTRACT

A semiconductor device includes: a silicon substrate having a main surface; an interlayer insulation film disposed on the main surface of the silicon substrate and having a top surface and a contact hole reaching the silicon substrate; a conductive film having a side surface and a top surface ranging from the side surface and filling the contact hole; a bottom electrode disposed in contact with the top and side surfaces of the conductive film; a dielectric film disposed on the bottom electrode; and a top electrode disposed on the dielectric film. The conductive film has its top surface more distant from the main surface of the silicon substrate than the interlayer insulation film has its top surface. The semiconductor device can be microfabricated and a desired capacitor structure can also be obtained to provide the semiconductor device with high reliability.

### BACKGROUND OF THE INVENTION

1. Field of the Invention

The present invention relates generally to semiconductor devices and particularly to those having a capacitor.

2. Description of the Background Art

In recent years as semiconductor devices, dynamic random access memory (DRAM) in particular, are microfabricated a cylindrical capacitor structure capable of increasing a capacitor's effective area relative to a memory cell's projected area is frequently used. This cylindrical capacitor structure has a cylindrical bottom electrode, a dielectric film and a top electrode covering a surface of the bottom electrode, stacked in layers. One such cylindrical capacitor structure is employed in a semiconductor device, for example as disclosed in Japanese Patent Laying-Open No. 2002-76141 as conventional art.

As disclosed in the above document, the conventional semiconductor device includes a semiconductor substrate, an interlayer insulation film disposed on the semiconductor substrate and having a contact hole reaching a main surface of the semiconductor substrate, a plug polysilicon film filling a portion of the contact hole, a barrier metal film filling the remaining portion of the contact hole, a cylindrical bottom electrode disposed on a top surface of the interlayer insulation film in contact with the barrier metal film, a TaON film disposed on the bottom electrode, and a top electrode disposed on the TaON film. The bottom electrode is formed of ruthenium (Ru). The bottom electrode, the TaON film and the top electrode together form a capacitor. The barrier metal film is formed to have a top surface in the same plane as that of the interlayer insulation film.

The above semiconductor device is fabricated, as described hereinafter. On the semiconductor substrate at the interlayer insulation film a contact hole is provided to expose a portion of the main surface of the semiconductor substrate. The contact hole is filled initially with the plug polysilicon and then the barrier metal film of titanium (Ti)/titanium nitride (TiN) successively stacked in layers. The interlayer insulation film and the barrier metal film have their respective top surfaces covered with a cap oxide film vapor deposited. To limit a capacitor region the cap oxide film is patterned to allow the barrier metal film and interlayer insulation film to have their respective top surfaces partially exposed.

The patterned cap oxide film is provided at an entire surface thereof with ruthenium film vapor deposited to serve as the bottom electrode. The ruthenium film is chemically mechanically polished (CMPed) to expose a top surface of the cap oxide film. A cylindrical bottom electrode of ruthenium is thus formed. The cap oxide film is removed. On the bottom electrode a TaON film superior in dielectric constant is disposed. On the TaON a top electrode is formed.

If a semiconductor device having such a cylindrical capacitor is further microfabricated the capacitor needs to be increased in height to ensure its capacitance. Accordingly, the capacitor's aspect ratio tends to increase and the bottom electrode is formed to have an increased height and a narrowed geometry.

The bottom electrode having a narrow geometry, however, contacts the barrier metal layer and the interlayer insulation film over a reduced area and thus has poor contact therewith. As such, from the steps of forming the bottom electrode and removing the cap oxide film through forming the TaON film and the top electrode on the bottom electrode successively, the bottom electrode may peel off the top surface of the barrier metal film and that of the interlayer insulation film and collapse.

Furthermore the bottom electrode is formed of metal to enhance the capacitor in capacitance. However, as compared with contact between polysilicon, that between polysilicon and metal is inferior. As such, rather than using the barrier metal film, forming the bottom electrode of ruthenium directly on a plug polysilicon film further increases the possibility that the bottom electrode collapses. If the bottom electrode collapses during the process for fabricating the semiconductor device, it causes the capacitor to fail in operation or adjacent capacitors to short circuit or acts as a foreign matter and has a negative affect on the semiconductor device disadvantageously.

### SUMMARY OF THE INVENTION

Accordingly the present invention contemplates resolving the above disadvantages, allowing a semiconductor device to be microfabricated and also obtaining a desired capacitor structure to provide the semiconductor device with high reliability.

In accordance with the present invention a semiconductor device includes a semiconductor substrate having a main surface, an interlayer insulation film disposed on the main surface of the semiconductor substrate and having a top surface and a hole reaching the semiconductor substrate, a conductive film having a side surface and a top surface ranging from the side surface, and filling the hole, a bottom electrode disposed in contact with the conductive film's top and side surfaces, a dielectric film disposed on the bottom electrode, and a top electrode disposed on the dielectric film. The top surface of the conductive film is more distant from the main surface of the semiconductor substrate than the top surface of the interlayer insulation film is.

The foregoing and other objects, features, aspects and advantages of the present invention will become more apparent from the following detailed description of the present invention when taken in conjunction with the accompanying drawings.

### BRIEF DESCRIPTION OF THE DRAWINGS

In the drawings:

FIG. 1 is a cross section of a semiconductor device of the present invention in a first embodiment;

FIGS. 2-9 are cross sections illustrating a process for fabricating the semiconductor device shown in FIG. 1;

FIGS. 10-12 are cross sections of the semiconductor device of the present invention in second to fourth embodiments, respectively;

FIGS. 13-15 are cross sections illustrating a process for fabricating the semiconductor device shown in FIG. 12;

FIGS. 16 and 17 are cross sections of the semiconductor device of the present invention in fifth and sixth embodiments, respectively;

FIGS. 18-21 are cross sections illustrating a process for fabricating the semiconductor device shown in FIG. 17;

FIGS. 22-25 are cross sections of the semiconductor device of the present invention in seventh to tenth embodiments, respectively;

FIGS. 26-30 are cross sections illustrating a process for fabricating the semiconductor device shown in FIG. 25;

FIGS. 31-34 are cross sections of the semiconductor device of the present invention in 11th to 14th embodiments, respectively;

FIG. 35 is a perspective view of a bottom electrode shown in FIG. 34, as seen downward;

FIGS. 36-42 are cross sections illustrating a process for fabricating the semiconductor device shown in FIG. 34; and

FIG. 43 is a plan view of a bottom electrode and an insulation film as seen in a direction indicated by an arrow XLIII of FIG. 42.

### DESCRIPTION OF THE PREFERRED EMBODIMENTS

The present invention in embodiments will now be described with reference to the drawings.

### First Embodiment

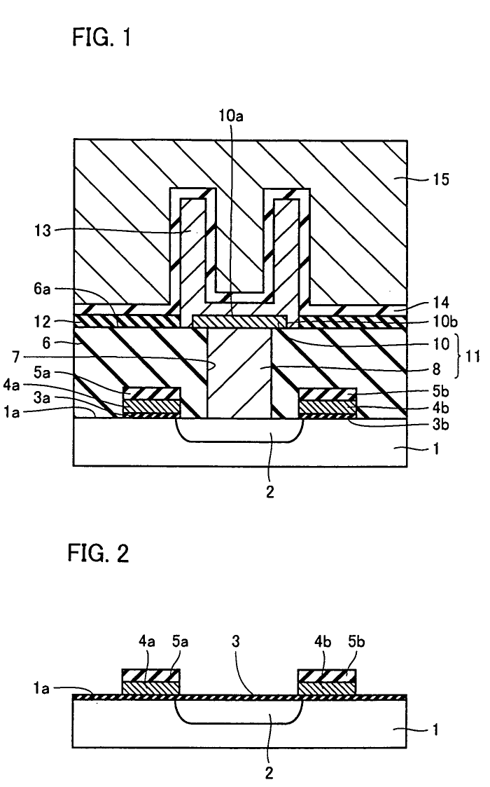

With reference to FIG. 1, the semiconductor device includes a cylindrical capacitor formed by a bottom electrode 13 formed in a cylinder, a dielectric film 14 formed along a surface of bottom electrode 13, and a top electrode 15 formed to cover dielectric film 14.

On a silicon substrate 1 at a main surface 1a gate electrodes 4a and 4b are formed, spaced as prescribed, with gate insulation films 3a and 3b interposed. Gate electrodes 4a and 4b are formed by initially stacking polysilicon and then tungsten silicide (WSi) in films. Gate electrodes 4a and 4b may be formed of polysilicon/tungsten nitride (WN)/tungsten (W) or polysilicon/titanium nitride (TiN)/tungsten stacked in films. Between gate electrodes 4a and 4b in a main surface la of silicon substrate 1 an n doped region 2 is formed. Gate electrodes 4a and 4b have their respective top surfaces provided with insulation film masks 5a and 5b formed of silicon nitride film.

An interlayer insulation film 6 is provided to cover main surface 1a of silicon substrate 1 and top surfaces of insulation film masks 5a and 5b, respectively. Interlayer insulation film 6 is formed of silicon oxide film, for example by initially stacking tetra ethyl ortho silicate (TEOS), then boro phospho tetra ethyl ortho silicate (BPTEOS) thereon and then TEOS thereon in layers. Interlayer insulation film 6 is provided with a contact hole 7 reaching doped region 2. Contact hole 7 is filled with doped polysilicon to form a plug electrode 8. Plug electrode 8 is formed to have a top surface in the same plane as a top surface 6a of interlayer insulation film 6.

On top surface 6a a barrier metal film 10 of tantalum nitride (TaN) is formed in contact with plug electrode 8. Barrier metal film 10 completely covers a top surface of plug electrode 8. Barrier metal film 10 may be formed of titanium (Ti), tantalum (Ta), titanium nitride (TiN), titanium tungsten (TiW), tungsten nitride (WN), tungsten-titanium nitride (WTiN), zirconium nitride (ZrN), titanium oxynitride (TiON) or the like. Alternatively, barrier metal film 10 may be formed by: initially stacking titanium and then titanium nitride thereon; initially stacking titanium, then titanium nitride thereon and then titanium thereon; or initially stacking tantalum nitride and then tantalum thereon in layers. Barrier metal film 10 has a top surface 10a positioned parallel to main surface 1a of silicon substrate 1 and higher in level than top surface 6a of interlayer insulation film 6, and a side surface 10b extending from top surface 10a toward top surface 6a of interlayer insulation film 6. Plug electrode 8 and barrier metal film 10 together form conductive film 11.

On interlayer insulation film 6 at top surface 6a an etching stopper film 12 is formed having a hole with an opening at a location spaced from side surface 10b of barrier metal 10. Etching stopper film 12 is formed of silicon nitride film. On top surface 6a bottom electrode (a storage node) 13 is formed of ruthenium (Ru). Bottom electrode 13 is formed in contact with top and side surfaces 10a and 10b of barrier metal film 10 and a portion of top surface 6a of interlayer insulation film 6. Bottom electrode 13 is formed to sandwich side surface 10b of barrier metal film 10. Bottom electrode 13 has a cylindrical geometry with an upper portion opened and its cylindrical portion is formed to extend in a direction away from main surface la of silicon substrate 1. Bottom electrode 13 may be formed of platinum (Pt), indium (In), gold (Au), silver (Ag) or the like.

Bottom electrode 13 and etching stopper film 12 are covered with dielectric film 14 formed of Ta₂O₅. Dielectric film 14 is covered with top electrode (a cell plate) 15 formed of ruthenium. Note that dielectric film 14 may be formed of SiO₂, SiN, BST((Ba, Sr)TiO₃), aluminum oxide (Al₂O₃), hafnium oxide (HfO₂), or lead zirconate titanate (PZT). Furthermore, top electrode 15 may be formed of titanium nitride (TiN), platinum (Pt), iridium (Ir), copper (Cu), silver (Ag), or gold (Au). In this example, dielectric film 14 and top electrode 15 are representatively used in a combination of Ta₂O₅/TiN, BST/Pt or PZT/Pt.

Thus forming bottom electrode 13 of metal can provide a capacitor with better capacitance than forming bottom electrode 13 of polysilicon, for the following reason: in general, dielectric film is based on oxide film. As such, if a bottom electrode is formed of polysilicon and dielectric film is disposed the bottom electrode has a surface oxidized. The oxidized portion of the bottom electrode acts as dielectric film. Accordingly, the dielectric film has an increased effective thickness. It is well known that a capacitor has capacitance in inverse proportion to thickness of dielectric film. Accordingly the capacitor has decreased capacitance. In contrast, forming bottom electrode 13 of metal can prevent such a detriment. Note that ruthenium oxidized is also conductive and platinum is hardly oxidized, and accordingly it is particularly noted that the bottom electrode is formed of ruthenium and platinum.

Furthermore in the present embodiment between bottom electrode 13 and plug electrode 8 barrier metal film is interposed. If barrier metal film 10 is not interposed, bottom electrode 13 and plug electrode 8 would directly contact each other and reaction between metal and polysilicon would be an issue. More specifically, if metal and polysilicon in contact with each other are heated to high temperature then at their interface a reaction is caused and metal silicon (metal silicide) forms. Typically, the metal absorbs the silicon and polysilicon (plug electrode 8) would have a defect or a cavity formed therein. Plug electrode 8 and bottom electrode 13 contacting each other in a plane having a defect or a cavity would contact each other over a reduced area and thus have poor contact therebetween. Furthermore, contact resistance between bottom electrode 13 and plug electrode 8 is also disadvantageously increased.

Such a detriment as described above is prevented in the present embodiment by providing barrier metal film 10. However, the present invention is also applicable if barrier metal 10 is not provided. This can be achieved simply by forming plug electrode 8 to have a top surface higher in level than top surface 6a of interlayer insulation film 6, and covering plug electrode 8 with bottom electrode 13.

The present semiconductor device in the first embodiment includes: silicon substrate 1 having main surface 1a and serving as a semiconductor substrate; interlayer insulation film 6 disposed on main surface 1a of silicon substrate 1 and having top surface 6a and contact hole as a hole 7 reaching silicon substrate 1; conductive film 11 having side surface 10b and top surface 10a ranging to side surface 10b, and filling contact hole 7; bottom electrode 13 disposed in contact with top and side surfaces 10a and 10b of conductive film 11; dielectric film 14 disposed on bottom electrode 13, and top electrode 15 disposed on dielectric film 14. Conductive film 11 has top surface 10a more distant from main surface 1a of silicon substrate 1 than interlayer insulation film 6 has top surface 6a.

Conductive film 11 includes barrier metal film 10 disposed in contact with bottom electrode 13 and serving as a barrier metal layer containing as tantalum nitride at least one selected from the group consisting of titanium, tantalum, titanium nitride, tantalum nitride, titanium tungsten, tungsten nitride, tungsten-titanium nitride, zirconium nitride, and titanium oxynitride. Bottom electrode 13 contains ruthenium serving as metal.

Note that while in the present embodiment the semiconductor device includes a cylindrical capacitor, the present invention is not limited thereto. The present invention is in particular applied to semiconductor devices that have a bottom electrode with an aspect ratio (the height of the electrode/the width of the electrode) of no less than one.

Reference will now be made to FIGS. 1-9 to describe a method of fabricating the semiconductor device shown in FIG. 1.

With reference to FIG. 2, on silicon substrate 1 at main surface 1a a silicon oxide film is formed to have a thickness of approximately several nm. Thereon a polysilicon film is initially is deposited and thereon a tungsten silicide film is then deposited. Furthermore thereon a silicon nitride film is formed. A resist film (not shown) having an opened pattern, as prescribed, is formed. With the resist film used as a mask, the silicon nitride film is etched to form insulation film masks 5a and 5b. With masks 5a and 5b used as a mask, the polysilicon film and the tungsten silicide film are etched to form gate electrodes 4a and 4b having a prescribed geometry, with gate insulation film 3 posed therebetween. With masks 5a and 5b used as a mask, silicon substrate 1 at main surface 1a receives phosphorus, arsenic or other similar dopant introduced thereinto to form n doped region 2.

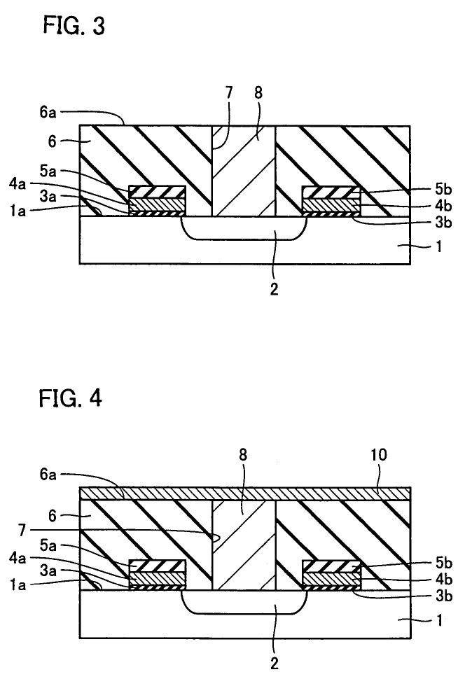

With reference to FIG. 3, main surface 1a of silicon substrate 1 and top surfaces respectively of masks 5a and 5b are covered with TEOS, BPTEO and TEOS successively deposited to form interlayer insulation film 6 of silicon oxide film. Interlayer insulation film 6 is provided on top surface 6a with a resist film (not shown) having an opened pattern having a prescribed geometry. With this resist film used as a mask, interlayer insulation film 6 is etched to form contact hole 7 reaching doped region 2. Contact hole 7 is filled with and top surface 6a is covered with doped polysilicon film deposited. The doped polysilicon film is chemically mechanically polished or etched back and removed to expose top surface 6a of interlayer insulation film 6 while contact hole 7 is allowed to still have the doped polysilicon film remaining therein. Thus in contact hole 7 plug electrode 8 is formed.

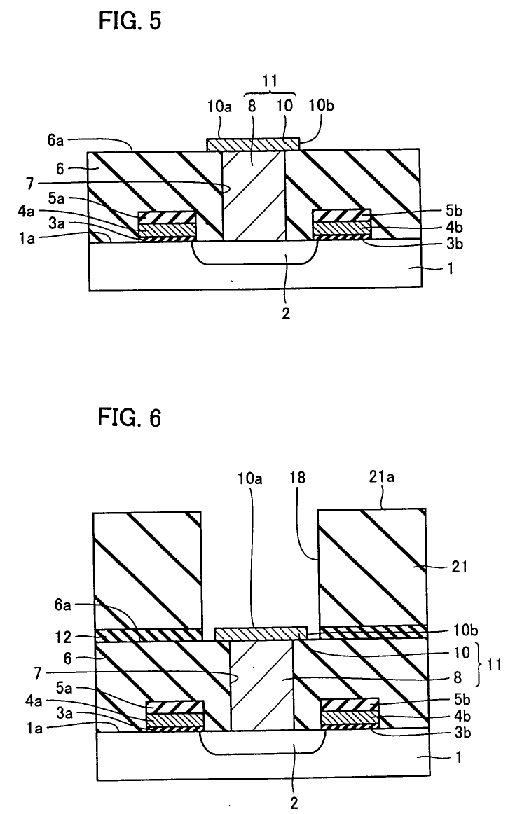

With reference to FIGS. 4 and 5, barrier metal film 10 is formed. More specifically, on interlayer insulation film 6 at top surface 6a a film of metal formed of tantalum nitride is deposited. On the film of metal a resist film (not shown) having an opened pattern having a prescribed geometry is formed. With this resist film used as a mask, the film of metal is etched to form barrier metal film 10 having a prescribed geometry.

With reference to FIG. 6, on interlayer insulation film 6 an etching stopper film 12 of silicon nitride and an interlayer insulation film 21 of silicon oxide formed using TEOS or the like as a raw material are successively deposited. Thereon a resist film (not shown) having an opened pattern having a prescribed geometry is formed. With this resist film used as a mask, the silicon oxide film and the silicon nitride film are etched to form a contact hole 18 opened to have a prescribed geometry.

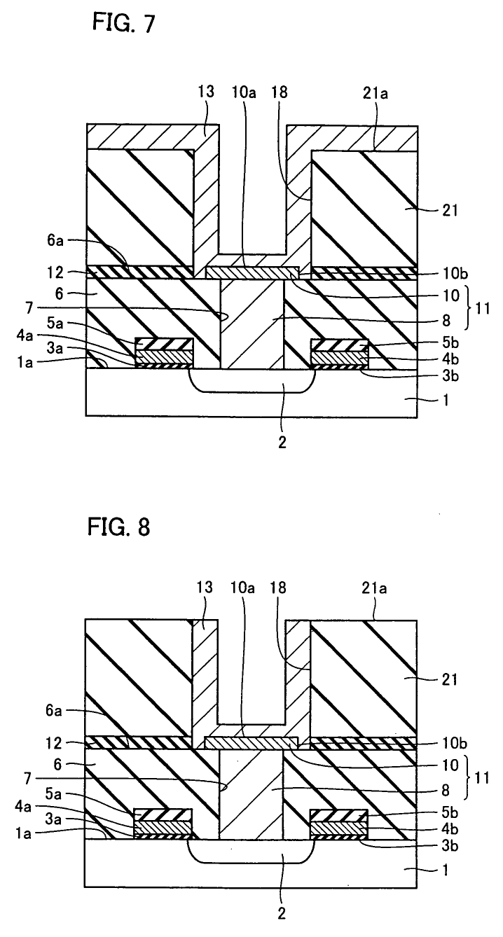

With reference to FIG. 7, bottom electrode 13 is formed. More specifically, a surface of contact hole 18 and a top surface 21a of interlayer insulation film 21 are covered with a film of metal formed of ruthenium deposited.

With reference to FIG. 8, the film of metal formed of ruthenium is chemically mechanically polished or dry- or wet-etched away to expose top surface 21a of interlayer insulation film 21. If it is dry etched, it is etched in a plasma using O₂/Cl₂ gas. Note that if bottom electrode 13 is formed of platinum, then it can satisfactorily be etched in a plasma using Cl₂/Ar gas. Furthermore, a depression defined by a film of metal located at contact hole 18 formed in interlayer insulation film 21 may be filled with organic protection film to prevent removal of the film of metal. Bottom electrode 13 having a cylindrical geometry is thus formed.

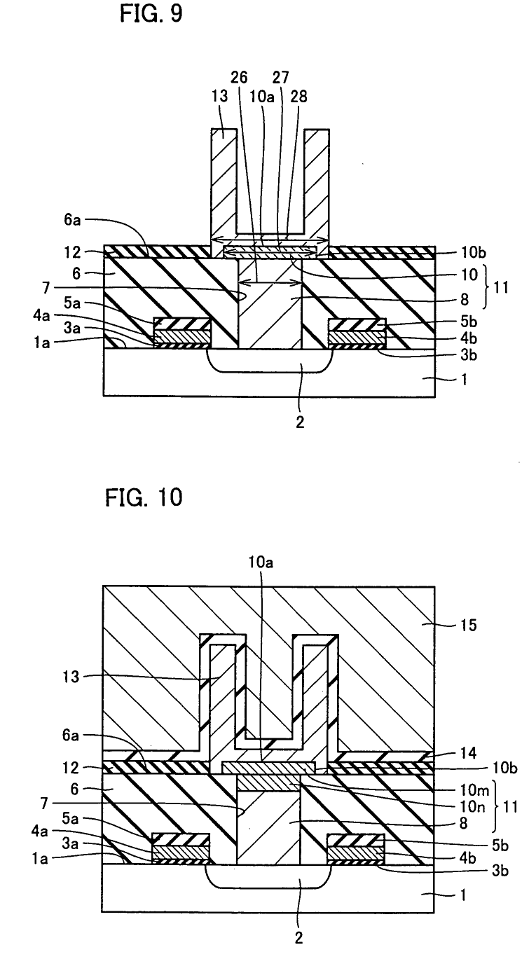

With reference to FIG. 9, an aqueous solution of hydrofluoric acid is used to wet etch interlayer insulation film 21 away from etching stopper film 12. Since interlayer insulation film 21 formed of silicon oxide film is removed by wet etching, a larger etch selectivity can be adopted relative to ruthenium and silicon nitride film than when interlayer insulation film 21 is dry etched. This can maximally reduce damage to bottom electrode 13 and etching stopper film 12.

In the present embodiment the semiconductor device is characterized in that when plug electrode 8, barrier metal film 10 and bottom electrode 13 are seen in cross section on a plane parallel to main surface 1a of silicon substrate 1, plug electrode 8 has the smallest area, as indicated by the length of an arrow 26, barrier metal film 10 has the second smallest area, as indicated by the length of an arrow 27, and bottom electrode 13 has the largest area, as indicated by the length of an arrow 28.

With reference to FIG. 1, bottom electrode 13 and etching stopper film 12 are covered with a thin film of Ta₂O₅ deposited to form dielectric film 14. Dielectric film 14 is covered with a film of metal of ruthenium deposited to form top electrode 15. The semiconductor device shown in FIG. 1 thus completes.

In the semiconductor device thus configured, bottom electrode 13 is provided to sandwich conductive film 11 located on top surface 6a of interlayer insulation film 6. More specifically, bottom electrode 13 is provided to sandwich side surface 10b of barrier metal film 10 serving as a constituent of conductive film 11. Furthermore, top surface 10a of barrier metal film 10 is higher in level than top surface 6a of interlayer insulation film 6. As such, as seen in a plane parallel to main surface 1a of silicon substrate 1, barrier metal film 10 can have a larger area as seen in cross section than contact hole 7. As such, even if microfabricating a semiconductor device results in contact hole 7 having an opening with a limited area, bottom electrode 13 and barrier metal film 10 can nonetheless contact each other over an increased area and hence more closely.

Thus during a process for fabricating a semiconductor device bottom electrode 13 can be prevented from peeling off top surface 6a of interlayer insulation film 6 and collapsing. As such, a desired capacitor structure can be implemented and a highly reliable semiconductor device can be provided. Furthermore, bottom electrode 13 can have an increased aspect ratio (the electrode's height/the electrode's width) and the semiconductor device can thus be microfabricated.

### Second Embodiment

A second embodiment provides a semiconductor device different from that of the first embodiment in the configuration of conductive film 11. Accordingly, the overlapping configuration will not be described.

With reference to FIG. 10, contact hole 7 is filled for example with doped polysilicon to provide plug electrode 8. Plug electrode 8 is formed to have a top surface lower in level than top surface 6a of interlayer insulation film 6. A portion of contact hole 7 free of plug electrode 8 is filled with tantalum nitride to provide a barrier metal film 10n. Barrier metal film 10n is formed to have a top surface in the same plane as top surface 6a of interlayer insulation film 6. On interlayer insulation film 6 a barrier metal film 10m identical in geometry to barrier metal film 10 shown in FIG. 1 is formed in contact with barrier metal film 10n. Plug electrode 8 and barrier metal films 10n and 10m together form conductive film 11.

In the semiconductor device of the present invention in the second embodiment conductive film 11 includes barrier metal layer disposed in contact with bottom electrode 13 and having barrier metal film 10n formed to fill contact hole 7.

The semiconductor device thus configured can be as effective as described in the first embodiment. In addition, barrier metal film 10n filling a portion of contact hole 7 can prevent barrier metal films 10n and 10m from peeling off interlayer insulation film 6.

### Third Embodiment

A third embodiment provides a semiconductor device different from that of the first embodiment in the configuration of conductive film 11. Accordingly, the overlapping configuration will not be described.

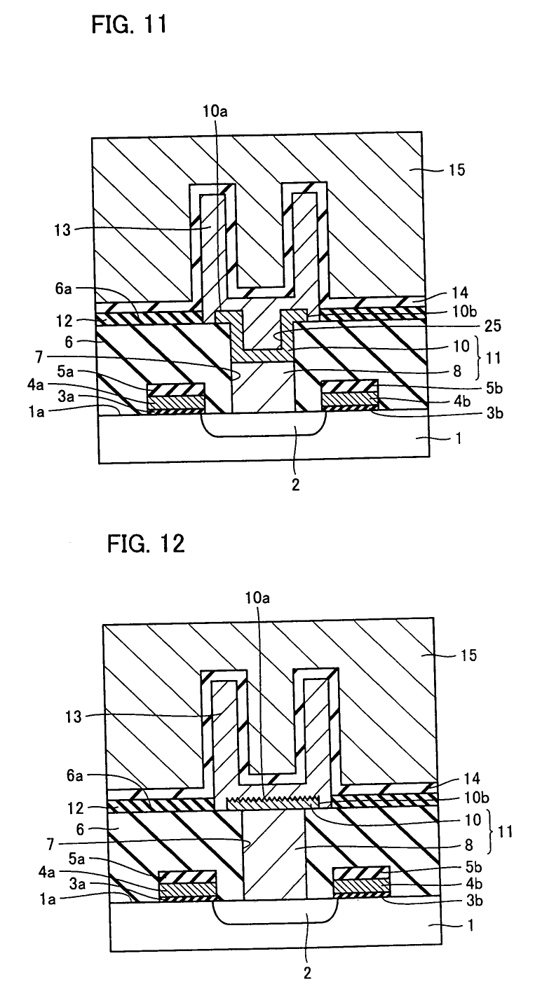

With reference to FIG. 11, contact hole 7 is filled for example with doped polysilicon to provide plug electrode 8. Plug electrode 8 is formed to have a top surface lower in level than top surface 6a of interlayer insulation film 6. A top surface of plug electrode 8, a sidewall of contact hole 7, and a portion of top surface 6a of interlayer insulation film 6 are covered with barrier metal film 10. Barrier metal film 10 has a top surface 10a higher in level than top surface 6a, and a side surface 10b extending from top surface 10a toward top surface 6a. Barrier metal film 10 has a recess 25 having an opening at top surface 10a. Plug electrode 8 and barrier metal film 10 together define conductive film 11. Bottom electrode 13 contacts top and side surfaces 10a and 10b and also fills recess 25.

In the semiconductor device of the present invention in the third embodiment conductive film 11 has recess 25 having an opening at top surface 10a serving as a top surface of conductive film 11. Bottom electrode 13 is formed to fill recess 25.

The semiconductor device thus configured can be as effective as described in the first embodiment. In addition, barrier metal film 10 having recess 25 allows bottom electrode 13 and barrier metal film 10 to contact each other over an increased area and hence more closely. Furthermore, bottom electrode 13 is fitted into a geometry formed of a protrusion and depression formed by side and top surfaces 10b and 10a of barrier metal film 10 and a surface of barrier metal film 10 that defines recess 25. The above reasons further ensure that during the process for fabricating the semiconductor device bottom electrode 13 can be prevented from peeling off top surface 6a of interlayer insulation film 6 and collapsing.

### Fourth Embodiment

A fourth embodiment provides a semiconductor device different from that of the first embodiment in the configuration of barrier metal film 10. Accordingly, the overlapping configuration will not be described.

With reference to FIG. 12, barrier metal film 10 has top surface 10a having an uneven geometry. Bottom electrode 13 is formed to mate on top surface 10a with the uneven geometry.

In the present semiconductor device in the fourth embodiment top surface 10a serving as a portion of conductive film 11 that contacts bottom electrode 13 has an uneven geometry.

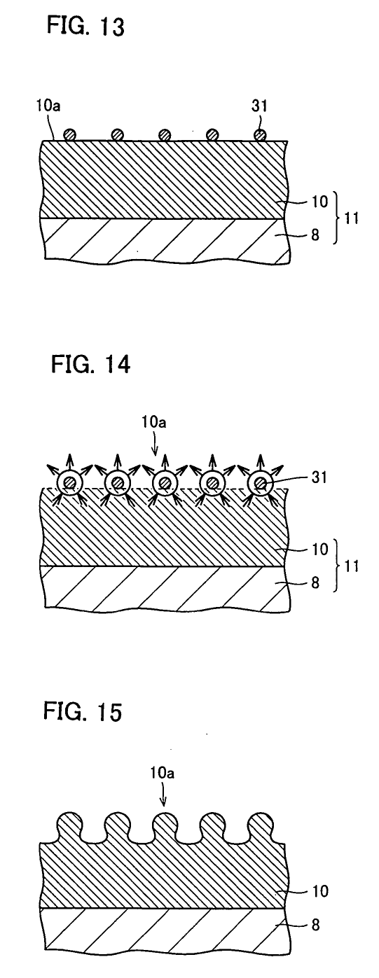

The FIGS. 2-4 steps of the method of fabricating the semiconductor device in the first embodiment are followed by the steps shown in FIGS. 13-15. Thereafter follow the FIGS. 6-9 steps of the method of fabricating the semiconductor device in the first embodiment and the FIG. 1 step. In the following, the overlapping fabrication steps will not be described.

With reference to FIG. 13, barrier metal film 10 is formed, as follows: on interlayer insulation film 6 at top surface 6a a film of metal formed of amorphous tantalum nitride is deposited. On a surface of the film of metal a Ta particle 31 is adhered. The particle serves as a nucleus and will be grown.

With reference to FIGS. 14 and 15 the film of metal formed of amorphous tantalum nitride is heated in a high vacuum. Ta particle 31 on the film of metal is grown into a crystal, eroding an amorphous portion of the film of metal. Barrier metal film 10 thus has top surface 10a formed to have an uneven geometry.

The semiconductor device thus configured can be as effective as described in the first embodiment. In addition, barrier metal film 10 having top surface 10a with an uneven geometry allows bottom electrode 13 and barrier metal film 10 to contact each other over an increased area and hence more closely to further ensure that during the process for fabricating the semiconductor device bottom electrode 13 can be prevented from peeling off top surface 6a of interlayer insulation film 6 and collapsing.

### Fifth Embodiment

A fifth embodiment provides a semiconductor device different from that of the fourth embodiment in the configuration of conductive film 11. Accordingly, the overlapping configuration will not be described.

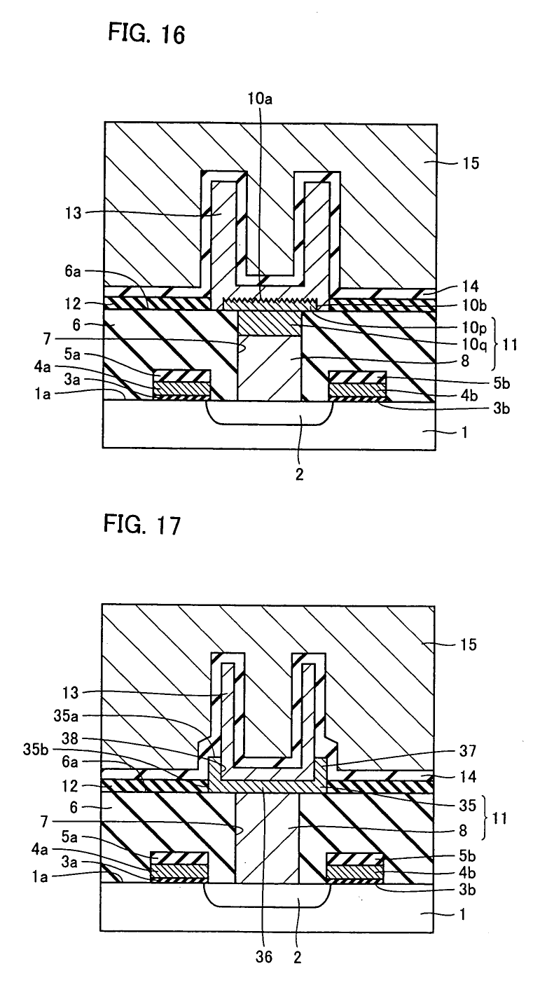

With reference to FIG. 16, contact hole 7 is filled for example with doped polysilicon to provide plug electrode 8. Plug electrode 8 is formed to have a top surface lower in level than top surface 6a of interlayer insulation film 6. A portion of contact hole 7 free of plug electrode 8 is filled with tantalum nitride to provide a barrier metal film 10q. Barrier metal film 10q is formed to have a top surface in the same plane as top surface 6a of interlayer insulation film 6. On interlayer insulation film 6 a barrier metal film 10p identical in geometry to barrier metal film 10 shown in FIG. 12 is formed in contact with barrier metal film 10q. Plug electrode 8 and barrier metal films 10p and 10q together form conductive film 11.

The semiconductor device thus configured can be as effective as described in the fourth embodiment. In addition, barrier metal film 10q filling a portion of contact hole 7 can prevent barrier metals 10p and 10q from peeling off interlayer insulation film 6.

### Sixth Embodiment

A sixth embodiment provides a semiconductor device different from that of the first embodiment in the configuration of conductive film 11. Accordingly, the overlapping configuration will not be described.

With reference to FIG. 17, on interlayer insulation film 6 at top surface 6a a barrier metal film 35 formed of tantalum nitride is provided in contact with plug electrode 8. Barrier metal film 35 completely covers a top surface of plug electrode 8. Barrier metal film 35 may be formed for example of titanium, as is barrier metal film 10 in the first embodiment. Alternatively, barrier metal film 35 may be formed by initially depositing titanium and then titanium nitride thereon in a stack of layers.

Barrier metal film 35 has a top surface 35a parallel to main surface 1a of silicon substrate 1 and higher in level than top surface 6a of interlayer insulation film 6, and a side surface 35b extending from top surface 35a toward top surface 6a of interlayer insulation film 6. Barrier metal film 35 has a recess 38 having an opening at top surface 35a. Recess 38 has a bottom surface more distant from main surface 1a of silicon substrate 1 than interlayer insulation film 6 has top surface 6a. Barrier metal film 35 is formed by a base 36 positioned on top surface 6a of interlayer insulation film 6 and a sidewall 37 extending upward from a periphery of base 36. Plug electrode 8 and barrier metal film 35 together form conductive film 11.

Bottom electrode 13 is fitted into recess 38 formed in barrier metal film 35. This allows bottom electrode 13 to have an outer peripheral surface supported by an inner peripheral surface of sidewall 37 of barrier metal film 35.

The present invention in the sixth embodiment provides a semiconductor device including: silicon substrate 1 having main surface la; interlayer insulation film 6 disposed on main surface 1a of silicon substrate 1 and having top surface 6a and contact hole 7 reaching silicon substrate 1; conductive film 11 having top surface 35a more distant from main surface 1a of silicon substrate 1 than top surface 6a of interlayer insulation film 6, and filling contact hole 7; bottom electrode 13 disposed on interlayer insulation film 6 in contact with conductive film 11; dielectric film 14 disposed on bottom electrode 13, and top electrode 15 disposed on dielectric film 14. Conductive film 11 includes base 36 formed on top surface 6a of interlayer insulation film 6 and sidewall 37 ranging from base 36 and extending away from main surface 1a of silicon substrate 1. Bottom electrode 13 is formed in contact with base 36 and sidewall 37.

Conductive film 11 includes barrier metal film 35 disposed in contact with bottom electrode 13 and serving as a barrier metal layer containing as tantalum nitride at least one selected from the group consisting of titanium, tantalum, titanium nitride, tantalum nitride, titanium tungsten, tungsten nitride, tungsten-titanium nitride, zirconium nitride, and titanium oxynitride. Bottom electrode 13 contains ruthenium serving as metal.

Note that while in the present embodiment the barrier metal film 35 recess 38 has a flat bottom surface, it may have an uneven bottom surface, as does the barrier metal film 10 top surface 10a shown in FIG. 12. In this example the portion of conductive film 11 that contacts bottom electrode 13 has an uneven geometry.

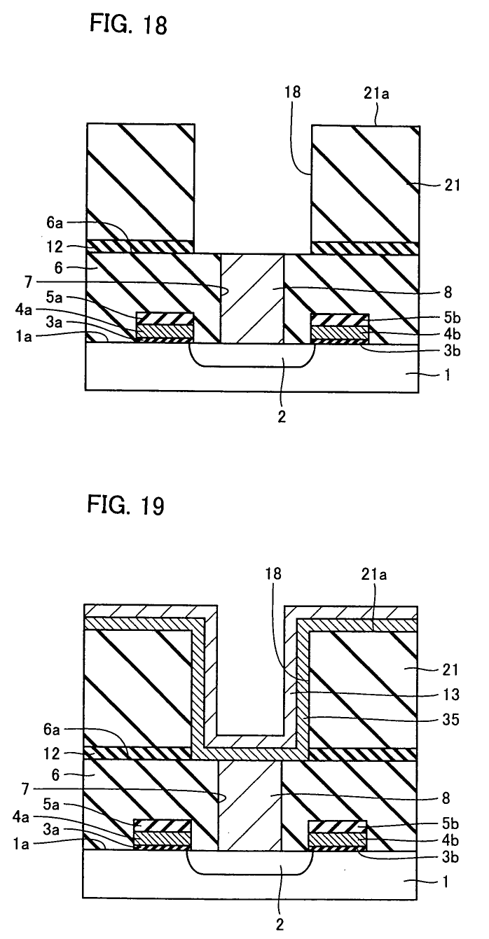

The FIGS. 2 and 3 steps of the method of fabricating the semiconductor device in the first embodiment are followed by the steps shown in FIGS. 18-21. Thereafter follows the FIG. 1 step of the method of fabricating the semiconductor device in the first embodiment. In the following, the overlapping fabrication steps will not be described.

With reference to FIG. 18, on interlayer insulation film 6 at top surface 6a etching stopper film 12 formed of silicon nitride film is deposited and thereon an interlayer insulation film 21 formed of silicon oxide film using TEOS as a raw material is deposited. Thereon a resist film (not shown) having an opened pattern having a prescribed geometry is formed. With this resist film used as a mask, the silicon oxide film and the silicon nitride film are etched to form a contact hole 18 opened to have a prescribed geometry.

With reference to FIG. 19, barrier metal film 35 and bottom electrode 13 are formed, as follows: a surface of contact hole 18 and a top surface 21a of interlayer insulation film 21 are covered with a film of metal formed of tantalum nitride initially deposited and a film of metal formed of ruthenium then deposited thereon.

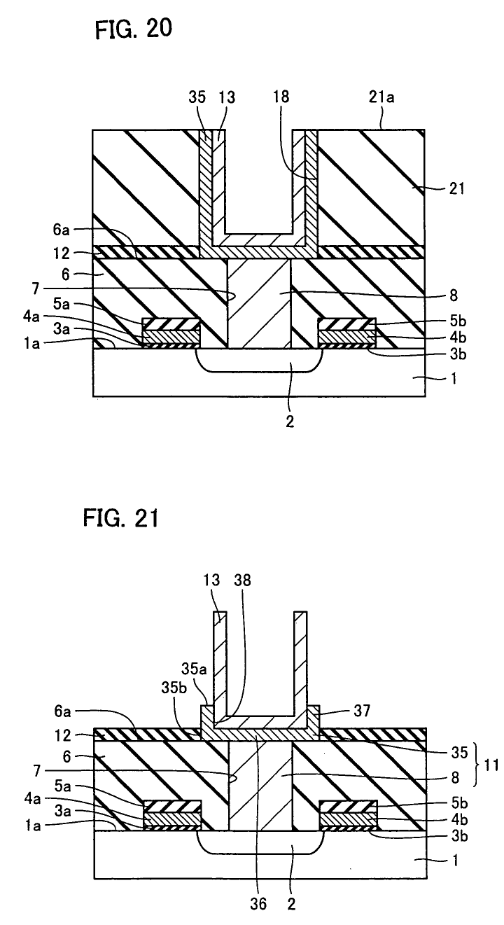

With reference to FIG. 20, the film of metal formed of ruthenium and that of metal formed of tantalum nitride are chemically mechanically polished or dry- or wet-etched away to expose top surface 21a of interlayer insulation film 21. The recess defined by the films of metal located in contact hole 18 formed in interlayer insulation film 21 may be filled with organic protection film to prevent removal of the films of metal. Cylindrical bottom electrode 13 and barrier metal film 35 are thus formed.

With reference to FIG. 21, wet etching is employed to remove interlayer insulation film 21 from etching stopper film 12. Simultaneously, barrier metal film 35 is also removed, although it should be noted that a condition of the etching is adjusted to allow barrier metal 35 to still have sidewall 37 surrounding an external peripheral surface of bottom electrode 13.

In the semiconductor device thus configured, bottom electrode 13 is supported by conductive film 11 located on top surface 6a of interlayer insulation film 6. More specifically, bottom electrode 13 is supported by sidewall 37 of barrier metal 35 serving as a constituent of conductive film 11. Furthermore, barrier metal film 35 has top surface 35a higher in level than top surface 6a of interlayer insulation film 6. At such, as seen in a plane parallel to main surface 1a of silicon substrate 1, barrier metal film 35 can have a larger area as seen in cross section than contact hole 7. As such, even if microfabricating a semiconductor device results in contact hole 7 having an opening with a limited area, bottom electrode 13 and barrier metal film 35 can nonetheless contact each other over an increased area and hence more closely.

Thus during a process for fabricating a semiconductor device bottom electrode 13 can be prevented from peeling off top surface 6a of interlayer insulation film 6 and collapsing. As such, a desired capacitor structure can be implemented and a highly reliable semiconductor device can be provided. Furthermore, bottom electrode 13 can have an increased aspect ratio (the electrode's height/the electrode's width) and the semiconductor device can thus be microfabricated.

### Seventh Embodiment

A seventh embodiment provides a semiconductor device different from that of the sixth embodiment in the configuration of conductive film 11. Accordingly, the overlapping configuration will not be described.

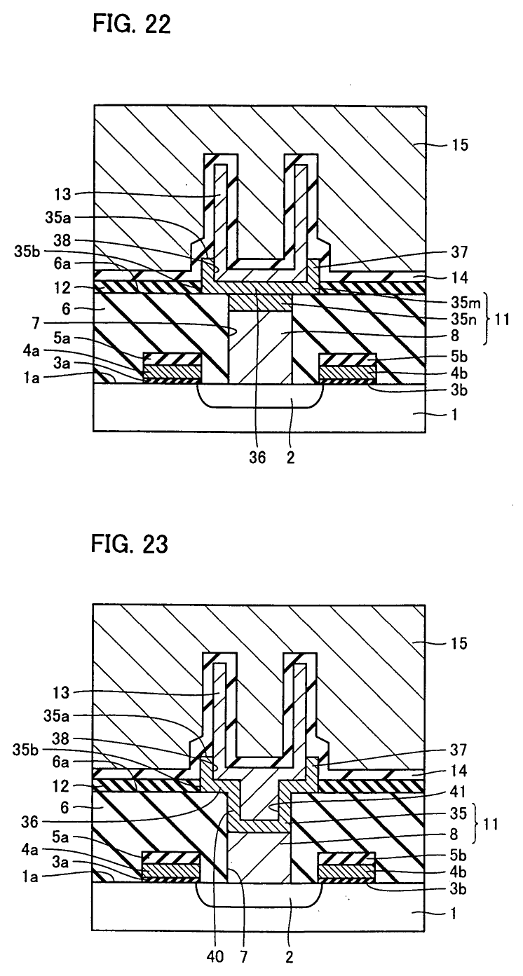

With reference to FIG. 22, contact hole 7 is filled for example with doped polysilicon to provide plug electrode 8. Plug electrode 8 is formed to have a top surface lower in level than top surface 6a of interlayer insulation film 6. A portion of contact hole 7 free of plug electrode 8 is filled with tantalum nitride to provide a barrier metal film 35n. Barrier metal film 35n is formed to have a top surface in the same plane as top surface 6a of interlayer insulation film 6. On interlayer insulation film 6 a barrier metal film 35m identical in geometry to barrier metal film 35 shown in FIG. 17 is formed in contact with barrier metal film 35n. Plug electrode 8 and barrier metal films 35n and 35m together form conductive film 11.

In the semiconductor device of the present invention in the seventh embodiment conductive film 11 includes barrier metal layer disposed in contact with bottom electrode 13 and having barrier metal film 35n formed to fill contact hole 7.

The semiconductor device thus configured can be as effective as described in the sixth embodiment. In addition, barrier metal film 35n filling a portion of contact hole 7 can prevent barrier metal films 35n and 35m from peeling off interlayer insulation film 6.

### Eighth Embodiment

An eighth embodiment provides a semiconductor device different from that of the sixth embodiment in the configuration of conductive film 11. Accordingly, the overlapping configuration will not be described.

With reference to FIG. 23, contact hole 7 is filled for example with doped polysilicon to provide plug electrode 8. Plug electrode 8 is formed to have a top surface lower in level than top surface 6a of interlayer insulation film 6. A top surface of plug electrode 8, a sidewall of contact hole 7, and a portion of top surface 6a of interlayer insulation film 6 are covered with barrier metal film 35. Barrier metal 35 is formed of a protrusion 40 formed to cover a top surface of plug electrode 8 and a sidewall of contact hole 7, a base 36 located on top surface 6a of interlayer insulation film 6, and a sidewall 37 extending upward from a periphery of base 36.

Barrier metal film 35 has a recess 38 having an opening at top surface 35a and a recess 41 having an opening at a bottom surface of recess 38. Recess 38 has the bottom surface more distant from main surface 1a of silicon substrate 1 than interlayer insulation film 6 has top surface 6a. Recess 41 has a bottom surface less distant from main surface 1a of silicon substrate 1 than interlayer insulation film 6 has top surface 6a.

Bottom electrode 13 is fitted into recesses 38 and 41 of barrier metal film 35. Thus bottom electrode 13 has a stepped, outer peripheral surface supported by recesses 38 and 41.

In the present semiconductor device of the eighth embodiment conductive film 11 further includes recess 41 having an opening in a plane contacting bottom electrode 13 and bottom electrode 13 fills recess 41.

The semiconductor device thus configured can be as effective as described in the sixth embodiment. In addition, barrier metal film 35 having recess 41 allows bottom electrode 13 and barrier metal film 35 to contact each other over an increased area. Furthermore, bottom electrode 13 is fitted into recesses 38 and 41 of barrier metal film 35. This further ensures that during the process for fabricating the semiconductor device bottom electrode 13 can be prevented from peeling off top surface 6a of interlayer insulation film 6 and collapsing.

### Ninth Embodiment

A ninth embodiment provides a semiconductor device different from that of the eighth embodiment in the configuration of conductive film 11. Accordingly, the overlapping configuration will not be described.

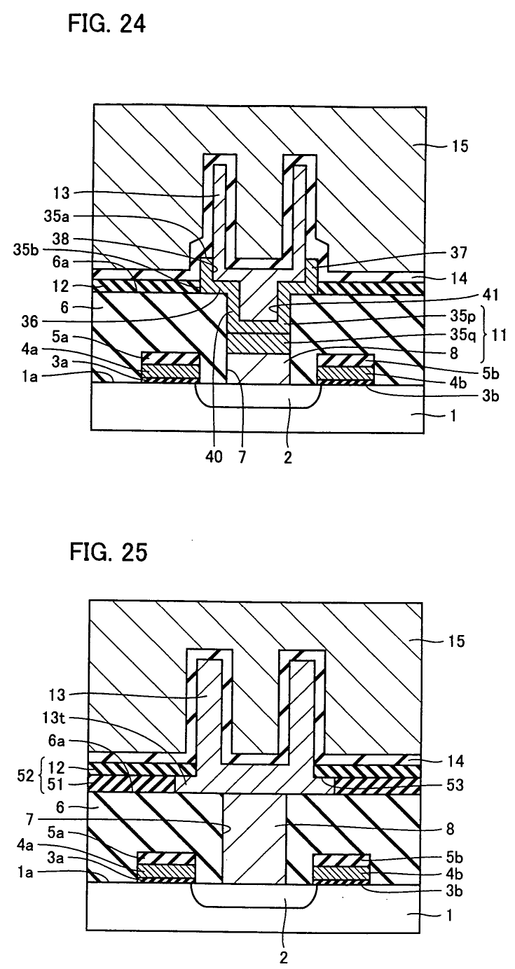

With reference to FIG. 24, plug electrode 8, a barrier metal film 35q provided on plug electrode 8, and a barrier metal film 35p provided on barrier metal film 35q and identical in geometry to barrier metal film 35 shown in FIG. 23 are formed in contact hole 7. Plug electrode 8 and barrier metal films 35p and 35q together formed conductive film 11.

The semiconductor film thus configured can be as effective as described in the eighth embodiment. In addition, barrier metal film 35p formed on plug electrode 8 with barrier metal film 35q posed therebetween can prevent barrier metal film from having small thickness on a top surface of plug electrode 8. This further ensures that reaction between plug electrode 8 of polysilicon and bottom electrode 13 of ruthenium can be prevented.

### Tenth Embodiment

A tenth embodiment provides a semiconductor device different from that of the first embodiment mainly in a configuration on interlayer insulation film 6. Accordingly, the overlapping configuration will not be described.

With reference to FIG. 25, interlayer insulation film 6 is formed of silicon oxide film using as a raw material BPTEOS having relatively low phosphorus and boron contents. On interlayer insulation film 6 at top surface 6a an insulation film 51 is formed having a hole exposing a portion of top surface 6a of interlayer insulation film 6 and a top surface of plug electrode 8. Insulation film 51 is formed of silicon oxide film using as a raw material BPTEOS having relatively high phosphorus and boron contents. On insulation film 51, etching stopper film 12 is formed having a hole smaller in diameter than the hole formed in insulation film 51. Etching stopper film 12 is formed of silicon nitride film. On interlayer insulation film 6 at top surface 6a, top surface 6a, a surface of the hole formed in interlayer insulation film 51, and a bottom surface of etching stopper film 12 that is opposite to top surface 6a together define a lateral hole 53. Insulation film 51 and etching stopper film 12 together form a holding film 52. Note that interlayer insulation film 6 may be formed of silicon oxide film using TEOS as a raw material and interlayer insulation film 51 may be formed of silicon oxide film using BPTEOS as a raw material.

On interlayer insulation film 6 at top surface 6a bottom electrode 13 is formed of ruthenium. Bottom electrode 13 has a jaw 13t protruding outward from an outer peripheral surface of bottom electrode 13. Bottom electrode 13 is formed with jaw 13t fitted into lateral hole 53.

The present invention in the tenth embodiment provides a semiconductor device including: silicon substrate 1 having main surface 1a; interlayer insulation film 6 disposed on main surface 1a of silicon substrate 1 and having top surface 6a and contact hole 7 reaching silicon substrate 1; plug electrode 8 filling contact hole 7 and serving as a conductive film; holding film 52 disposed on interlayer insulation film 6 and having lateral hole 53 extending along top surface 6a of interlayer insulation film 6; bottom electrode 13 having jaw 13t filling lateral hole 53, and contacting plug electrode 8; dielectric film 14 disposed on bottom electrode 13; and top electrode 15 disposed on dielectric film 14.

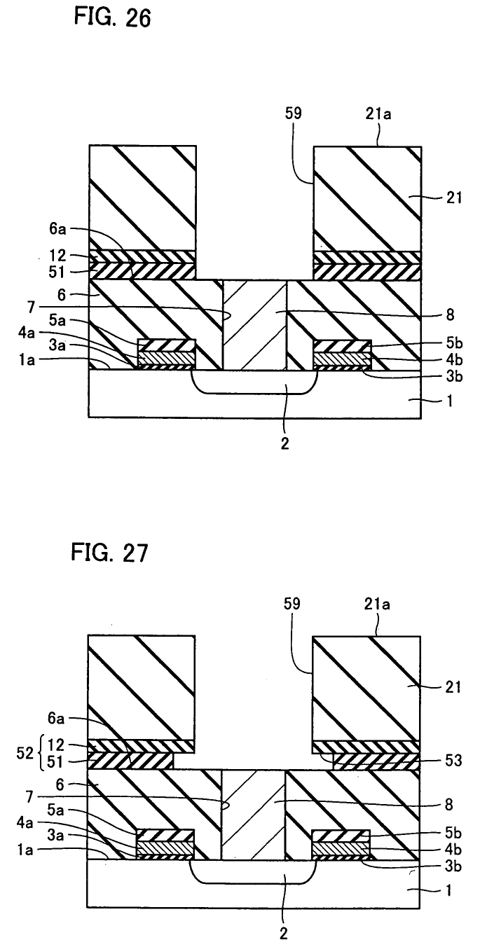

The FIGS. 2 and 3 steps of the method of fabricating the semiconductor device in the first embodiment are followed by the steps shown in FIGS. 26-30. Thereafter follows the FIG. 1 step of the method of fabricating the semiconductor device in the first embodiment. In the following, the overlapping fabrication steps will not be described.

With reference to FIG. 26, on interlayer insulation film 6 at top surface 6a, insulation film 51 formed of silicon oxide film using as a raw material BPTEOS having relatively high phosphorus and boron contents, etching stopper film 12 formed of silicon nitride film, and interlayer insulation film 21 formed of silicon oxide film using as a raw material BPTEOS having relatively low phosphorus and boron contents are deposited successively. Thereon a resist film (no shown) having an opened pattern having a prescribed geometry is formed. With this resist film used as a mask, the deposited silicon oxide and nitride films are etched to form a contact hole 59 having an opening of a prescribed geometry.

With reference to FIG. 27, insulation film 51 is isotropically etched to form lateral hole 53 at a prescribed position. In doing so, insulation film 51 and interlayer insulation films 6 and 21 having different phosphorus and boron contents allow a large etch selectivity to be adopted relative to interlayer insulation films 6 and 21. Accordingly, although isotropically etching insulation film 51 also causes interlayer insulation films 6 and 21 to recede, by causing insulation film 51 to further recede, lateral hole 53 of a prescribed geometry can be formed.

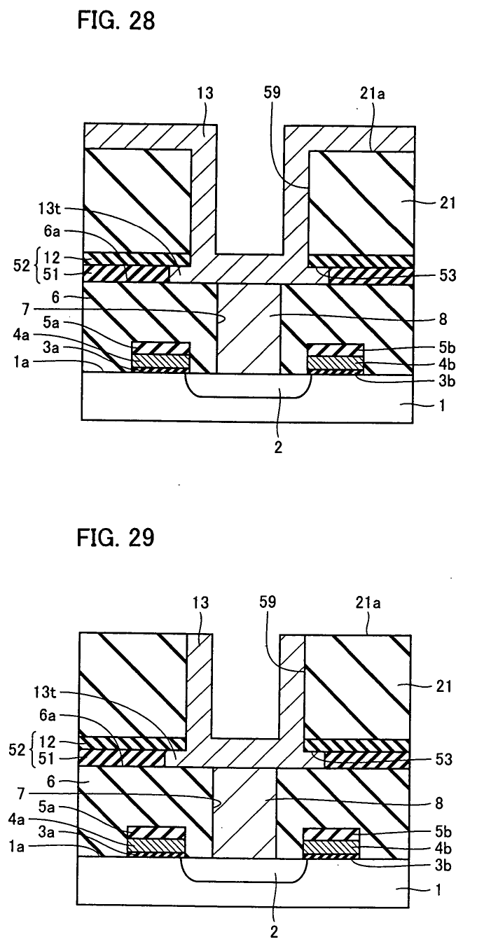

With reference to FIG. 28, bottom electrode 13 is formed, as follows: a film of metal formed of ruthenium is deposited to cover a surface of contact hole 59 and top surface 21a of interlayer insulation film 21 and also fill lateral hole 53.

With reference to FIG. 29, the film of metal formed of ruthenium is chemically mechanically polished or dry- or wet-etched away to expose top surface 21a of interlayer insulation film 21. The recess defined by the film of metal located in contact hole 59 formed in interlayer insulation film 21 may be filled with organic protection film to prevent removal of the film of metal. Cylindrical bottom electrode 13 is thus formed.

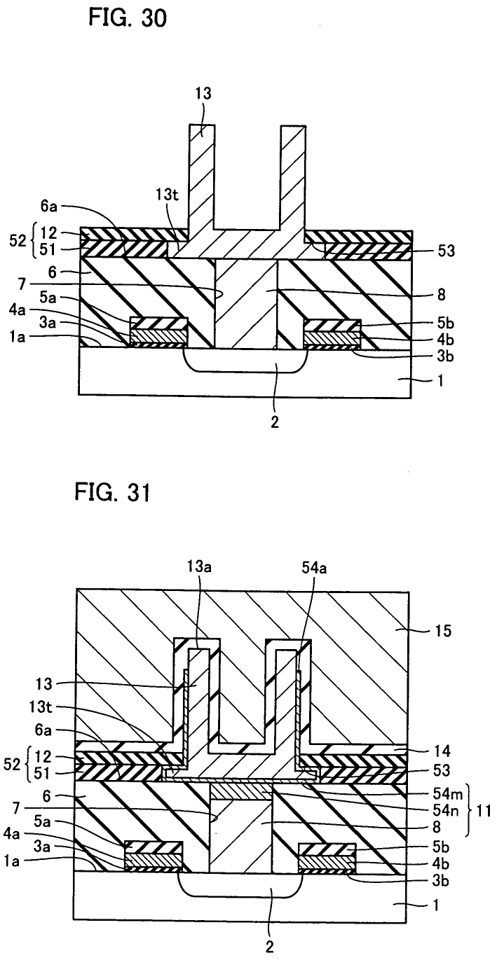

With reference to FIG. 30, wet etching is employed to remove interlayer insulation film 21 from etching stopper film 12.

In the semiconductor device thus configured, bottom electrode 13 has jaw 13t fitted into lateral hole 53 formed by holding film 52. Furthermore, jaw 13t is pressed toward top surface 6a of interlayer insulation film 6 by etching stopper film 12 serving as a constituent of holding film 52. As such during the process for fabricating the semiconductor device bottom electrode 13 can be prevented from peeling off top surface 6a of interlayer insulation film 6 and collapsing. Thus a desired capacitor structure can be implemented and a highly reliable semiconductor device can be provided. Furthermore bottom electrode 13 can have an increased aspect ratio (the electrode's height/the electrode's width) and the semiconductor device can be microfabricated.

### Eleventh Embodiment

An 11th embodiment provides a semiconductor device different from that of the tenth embodiment in the configuration of conductive film 11. Accordingly, the overlapping configuration will not be described.

With reference to FIG. 31, contact hole 7 is filled for example with doped polysilicon to provide plug electrode 8. Plug electrode 8 is formed to have a top surface lower in level than top surface 6a of interlayer insulation film 6. A portion of contact hole 7 free of plug electrode 8 is filled with tantalum nitride to provide a barrier metal film 54n. Barrier metal film 54n is formed to have a top surface in the same plane as top surface 6a of interlayer insulation film 6.

Barrier metal film 54m is formed to contact barrier metal film 54n and also cover an outer peripheral surface of bottom electrode 13. Barrier metal film 54m is formed to extend on top surface 6a of interlayer insulation film 6 through lateral hole 53 to the outer peripheral surface of bottom electrode 13. Plug electrode 8 and barrier metal films 54n and 54m together form conductive film 11.

Barrier metal film 54m has a top surface 54a lower in level than bottom electrode 13 has top surface 13a. Bottom electrode 13 has an opening at an upper end thereof. As such typically it is formed to extend outward as it is farther away from top surface 6a of interlayer insulation film 6. By forming barrier metal film 54m on an outer peripheral surface of bottom electrode 13 to be lower in level plan bottom electrode 13, adjacent bottom electrodes 13 can be prevented from contacting each other and short circuiting.

The semiconductor device thus configured can be as effective as described in the tenth embodiment. In addition, barrier metal film 54m extending upward along an outer peripheral surface of bottom electrode 13 can serve to support bottom electrode 13. This further ensure that during the process for fabricating the semiconductor device bottom electrode 13 can be prevented from peeling off top surface 6a of interlayer insulation film 6 and collapsing. Furthermore, barrier metal film 54m provided between bottom electrode 13 of ruthenium and plug electrode 8 of polysilicon can prevent electrodes 8 and 13 from reacting with each other. Furthermore, barrier metal film 54n posed between plug electrode 8 and barrier metal film 54m can prevent barrier metal film 54m from having a reduced thickness resulting in electrodes 8 and 13 reacting with each other.

### Twelfth Embodiment

A 12th embodiment provides a semiconductor device different from that of the tenth embodiment in the configuration of conductive film 11 and that of a lateral hole. Accordingly, the overlapping configuration will not be described.

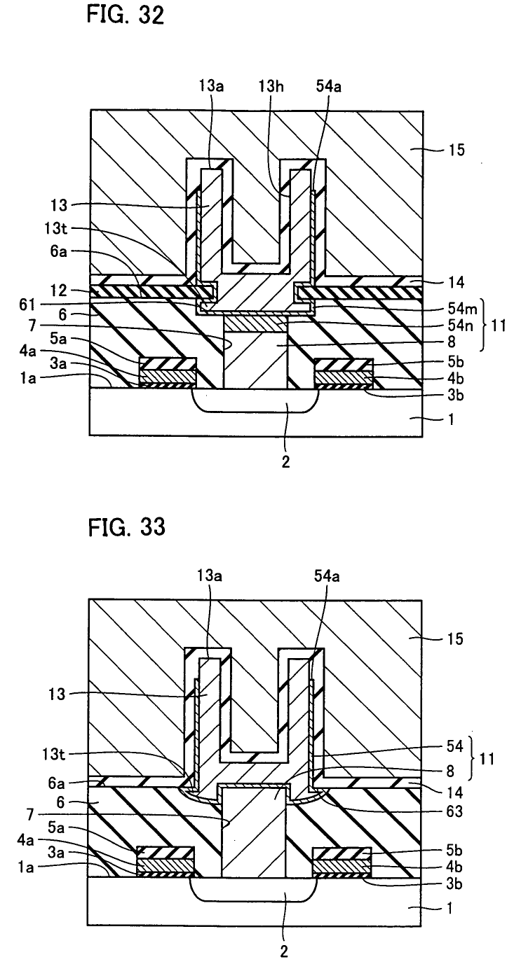

With reference to FIG. 32, on interlayer insulation film 6 etching stopper film 12 having a hole is formed. Interlayer insulation film 6 has a recess having an opening provided at top surface 6a and larger in diameter than the hole of etching stopper film 12. A surface of interlayer insulation film 6 that defines the recess and a bottom surface of etching stopper film 12 that is opposite to a bottom surface of the recess together define a lateral hole 61. Bottom electrode 13 at a bottom thereof has a jaw 13t fitted into lateral hole 61. Similarly as described in the 11th embodiment with reference to the FIG. 31 semiconductor device, barrier metal film 54n fills a portion of contact hole 7. Furthermore, barrier metal film 54m is formed to contact barrier metal film 54n and also cover an outer peripheral surface of bottom electrode 13.

In the present semiconductor device of the 12th embodiment lateral hole 61 is less distant from main surface 1a of silicon substrate 1 than top surface 6a of interlayer insulation film 6.

The semiconductor device thus configured can be as effective as described in the 11th embodiment. In addition, lateral hole 61 is defined by interlayer insulation film 6 and etching stopper film 12. This can eliminate the necessity of using an additional insulation film to form lateral hole 61. As such, the semiconductor device can be fabricated through a reduced number of fabrication steps.

### Thirteenth Embodiment

A 13th embodiment provides a semiconductor device different from that of the tenth embodiment in the configuration of conductive film 11 and that of a lateral hole. Accordingly, the overlapping configuration will not be described.

With reference to FIG. 33, dielectric film 14 serving as a holding film and a dielectric film is provided to cover bottom electrode 13 and top surface 6a of interlayer insulation film 6. Interlayer insulation film 6 is formed to have a portion located outer than an outer peripheral surface of plug electrode 8 and receding from top surface 6a. A surface of the receding portion of interlayer insulation film 6 and a surface of dielectric film 14 that is opposite to the receding portion of interlayer insulation film 6 together define a lateral hole 63. Bottom electrode 13 at a bottom thereof has jaw 13t radially extending to be fitted into lateral hole 63. Similarly as has been described in the 11th embodiment with reference to the FIG. 31 semiconductor device, barrier metal film 54 is provided to contact plug electrode 8 and also cover an outer peripheral surface of bottom electrode 13.

The semiconductor device thus configured can be as effective as described in the 11th embodiment. In addition, lateral hole 63 is defined by interlayer insulation film 6 and dielectric film 14. This can eliminate the necessity of employing an additional insulation film to inform lateral hole 63. The semiconductor device can be fabricated through a further reduced number of fabrication steps.

### Fourteenth Embodiment

A 14th embodiment provides a semiconductor device having a configuration overlapping that of the semiconductor device of the first embodiment. Hereinafter its configuration that is different from the semiconductor device of the first embodiment will mainly be described.

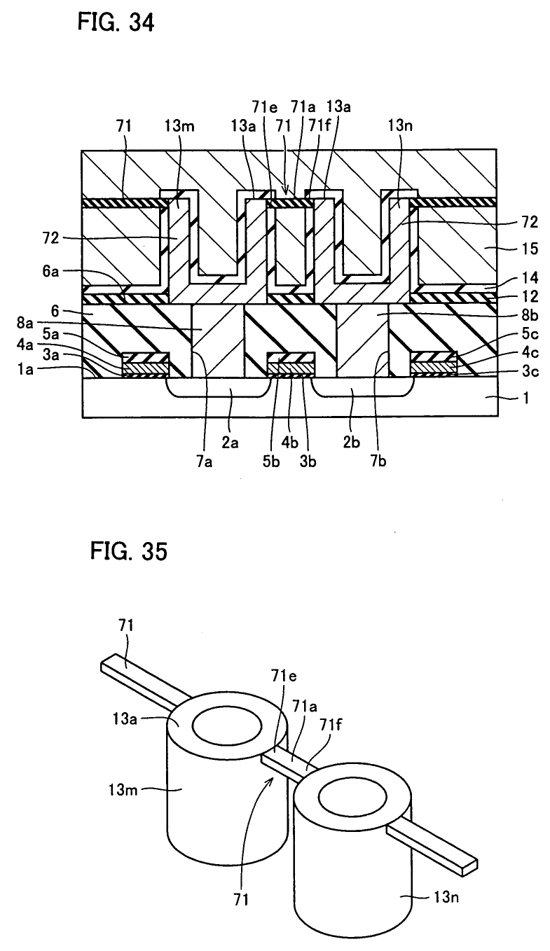

With reference to FIG. 34, similarly as described in the first embodiment with reference to the FIG. 1 semiconductor device, silicon substrate 1 has main surface 1a with gate electrodes 4a, 4b and 4c and insulation masks 5a, 5b and 5c formed thereon with gate insulation films 3a, 3b and 3c posed therebetween. In silicon substrate 1 at main surface 1a between gate electrodes 4a, 4b and 4c n doped regions 2a and 2b are formed.

Interlayer insulation film 6, covering main surface 1a of silicon substrate 1 and a top surface of each insulation film mask 5a, 5b, 5c, is provided with contact holes 7a and 7b reaching doped regions 2a and 2b. Contact holes 7a and 7b are filled for example with doped polysilicon to form plug electrodes 8a and 8b. On interlayer insulation film 6 at top surface 6aetching stopper film 12 is formed having an opening on plug electrodes 8a and 8b.

Bottom electrodes 13m and 13n are formed in contact with plug electrodes 8a and 8b. Bottom electrodes 13m and 13n have a cylindrical portion 72 located on top surface 6a of interlayer insulation film 6 and extending away from main surface 1a of silicon substrate 1. Cylindrical portion 72 has an upper end forming top surface 13a of bottom electrodes 13m and 13n. Bottom electrodes 13m and 13n have a surface covered with dielectric film 14. Dielectric film 14 is covered with top electrode 15.

With reference to FIGS. 34 and 35, an outer peripheral surface of bottom electrode 13m that is closer to top surface 13a and an outer peripheral surface of bottom electrode 13n that is closer to top surface 13a are linked together by an insulation film 71 formed of silicon nitride film. Insulation film 71 has one end 71e linked to bottom electrode 13m and the other end 71f linked to bottom electrode 13n. Top surface 13a of bottom electrodes 13m and 13n and a top surface 71a of insulation film 71 are in a single plane. Insulation film 71 is rectangular in cross section and formed to extend linearly.

The present invention in the 14th embodiment provides a semiconductor device including: silicon substrate 1 having main surface 1a; interlayer insulation film 6 formed on main surface 1a of silicon substrate 1 and having top surface 6a and a plurality of contact holes 7a and 7b reaching silicon substrate 1; plug electrodes 8a and 8b serving as first and second conductive films filling each of contact holes 7a and 7b; bottom electrodes 13m and 13n extending away from top surface 6a of interlayer insulation film 6, having cylindrical portion 72 serving as a portion provided with top surface 13a, and serving as first and second bottom electrodes formed in contact with plug electrodes 8a and 8b; insulation film 71 formed closer to top surface 13a of cylindrical portion 72 and having one and the other ends 71e and 71f connected to bottom electrodes 13m and 13n, respectively; dielectric film 14 disposed on bottom electrodes 13m and 13n; and top electrode 15 disposed on dielectric film 14.

Insulation film 71 has top surface 71a substantially in the same plane as top surface 13a of cylindrical portion 72.

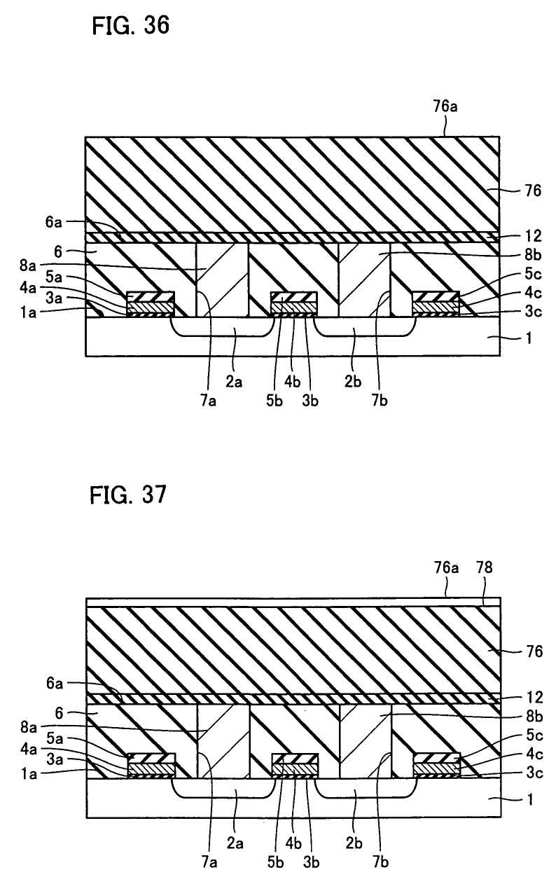

The FIGS. 2 and 3 steps of the method of fabricating the semiconductor device in the first embodiment are followed by the steps shown in FIGS. 36-42 and thereafter follows the FIG. 1 step of the method of fabricating the semiconductor device in the first embodiment. In the following, the overlapping fabrication steps will not be described.

With reference to FIG. 36, on interlayer insulation film 6 at top surface 6a etching stopper film 12 formed of silicon nitride film is initially deposited and thereon an interlayer insulation film 76 formed of silicon oxide film using TEOS as a raw material is then deposited. With reference to FIG. 37, thereon a resist film (not shown) having an opened pattern of a prescribed geometry is formed. With the resist film used as a mask, interlayer insulation film 76 is etched to form a trench 78 having a rectangular cross section and extending linearly.

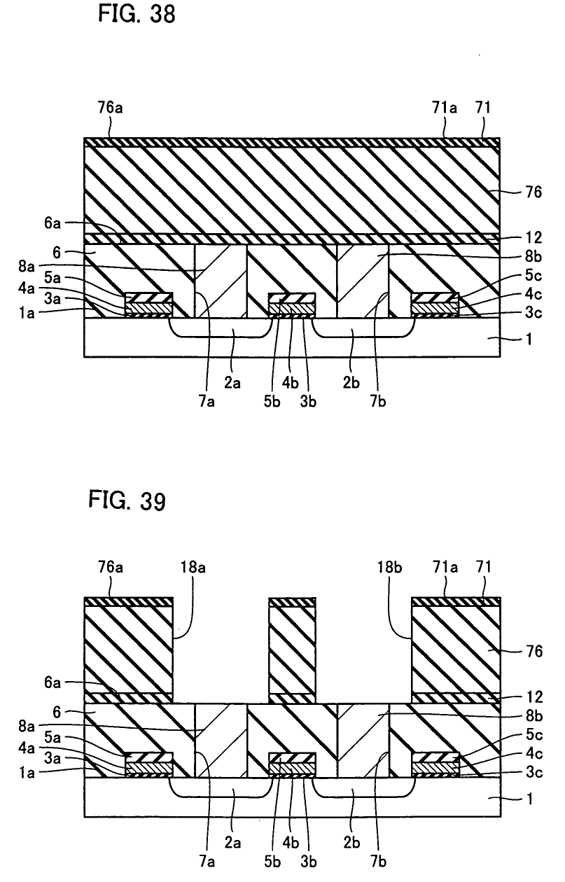

With reference to FIG. 38, trench 78 is filled with silicon nitride film to form insulation film 71. In doing so, a processing is effected to allow interlayer insulation film 76 and insulation film 71 to have their respective top surfaces 76a and 71a in a single plane.

With reference to FIG. 39, on insulation film 71 and interlayer insulation film 76 a resist film (not shown) having an opened pattern of a prescribed geometry is formed. With the resist film used as a mask, insulation film 71, interlayer insulation film 76 and etching stopper film 12 are etched to form contact holes 18a and 18b.

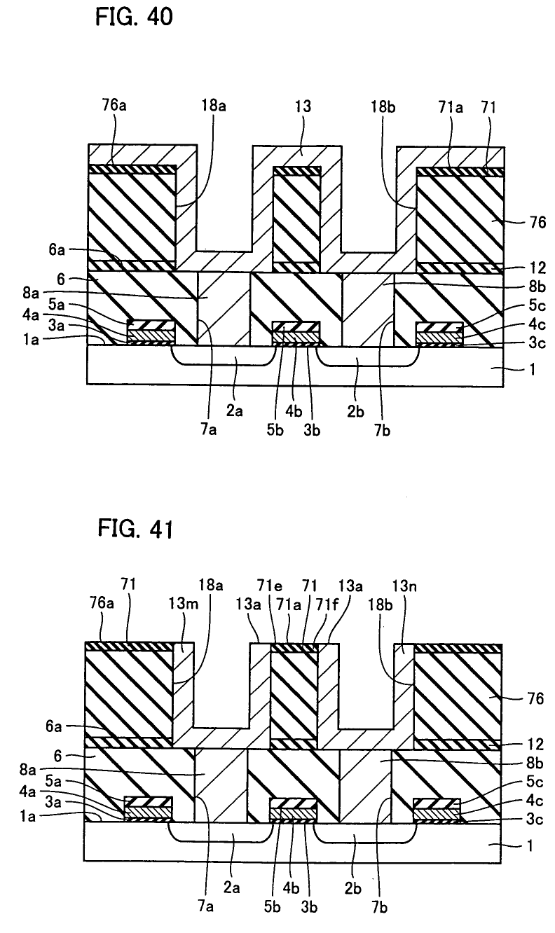

With reference to FIG. 40, bottom electrodes 13m and 13n are formed, as follows: a film of metal formed of ruthenium is deposited to cover a surface of contact holes 18a and 18b and top surface 76a of interlayer insulation film 76.

With reference to FIG. 41, the film of metal formed of ruthenium is chemically mechanically polished or dry- or wet-etched away to expose top surface 76a of interlayer insulation film 76. The recess defined by the film of metal located in contact holes 18a and 18b formed in interlayer insulation film 76 may be filled with organic protection film to prevent removal of the film of metal. Cylindrical bottom electrodes 13m and 13n are thus formed.

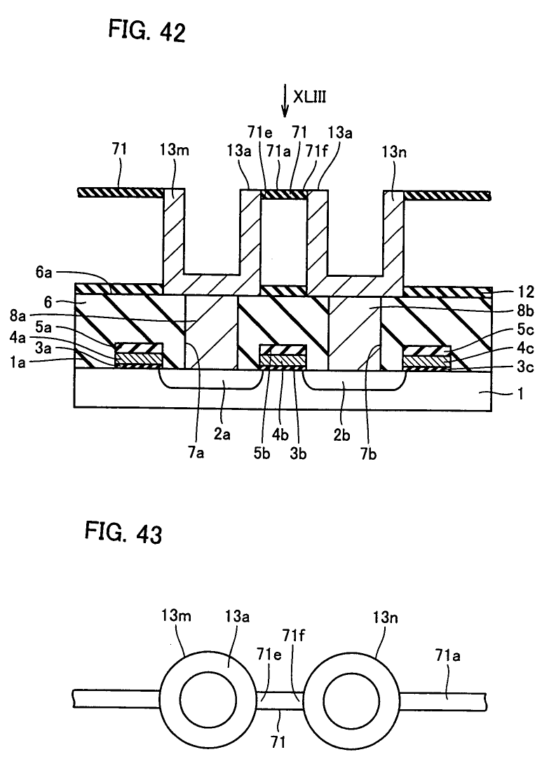

With reference to FIG. 42, wet etching is employed to remove interlayer insulation film 76 from etching stopper film 12. With reference to FIG. 43, insulation film 71 formed of silicon nitride film remains, connecting outer peripheral surfaces of bottom electrodes 13m and 13n, respectively.

In the semiconductor device thus configured, bottom electrodes 13m and 13n are supported by insulation film 71 connected to their respective outer peripheral surfaces. This can prevent bottom electrodes 13m and 13n from peeling off top surface 6a of interlayer insulation film 6 and collapsing during the process for fabricating the semiconductor device. Furthermore, interlayer insulation film 71 is connected to bottom electrodes 13m and 13n in a vicinity of top surface 13a. As such, top electrodes 13m and 13n have an upper portion supported by interlayer insulation film 71 and a lower portion supported by top surface 6a of interlayer insulation film 6 and those of plug electrodes 8a and 8b. Thus bottom electrodes 13m and 13n can more firmly be supported. This effect can be exhibited particularly when, as in the semiconductor device of the present embodiment, bottom electrodes 13m and 13n and insulation film 71 have their respective top surfaces 13a and 71a in a single plane.

Thus a desired capacitor structure can be implemented and a highly reliable semiconductor device can be provided. Furthermore, bottom electrodes 13m and 13n can have an increased aspect ratio (electrode height/electrode width) so that the semiconductor device can be microfabricated.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a semiconductor substrate having a main surface;
an interlayer insulation film formed on said main surface of said semiconductor substrate and having a top surface and a hole reaching said semiconductor substrate;
a conductive film having a side surface and a top surface ranging from said side surface and having a larger distance from said main surface of said semiconductor substrate than a distance from the main surface of said semiconductor substrate to said top surface of said interlayer insulation film, said conductive film filling said hole;
a bottom electrode disposed in contact with said top and side surfaces of said conductive film;
a dielectric film disposed on said bottom electrode; and
a top electrode disposed on said dielectric film.

2. The semiconductor device according to claim 1, wherein said conductive film includes a barrier metal layer disposed in contact with said bottom electrode and containing at least one selected from the group consisting of titanium, tantalum, titanium nitride, tantalum nitride, titanium-tungsten, tungsten nitride, tungsten-titanium nitride, zirconium nitride and titanium oxinitride, and said bottom electrode contains metal.

3. The semiconductor device according to claim 1, wherein said conductive film includes a barrier metal layer disposed in contact with said bottom electrode and having a portion formed to fill said hole.

4. The semiconductor device according to claim 1, wherein a portion of said conductive film contacting said bottom electrode has an uneven geometry.

5. The semiconductor device according to claim 1, wherein said conductive film has a recess having an opening at said top surface of said conductive film and said bottom electrode is formed to fill said recess.

6. A semiconductor device comprising:
a semiconductor substrate having a main surface;
an interlayer insulation film formed on said main surface of said semiconductor substrate and having a top surface and a hole reaching said semiconductor substrate;
a conductive film having a top surface having a larger distance from said main surface of said semiconductor substrate than a distance from the main surface of said semiconductor substrate to said top surface of said interlayer insulation film, said conductive film filling said hole, said conductive film having a base formed on said top surface of said interlayer insulation film, and a sidewall ranging from said base and extending away from said main surface of said semiconductor substrate;
a bottom electrode disposed on said interlayer insulation film in contact with said base and said sidewall;
a dielectric film disposed on said bottom electrode; and
a top electrode disposed on said dielectric film.

7. The semiconductor device according to claim 6, wherein said conductive film includes a barrier metal layer disposed in contact with said bottom electrode and containing at least one selected from the group consisting of titanium, tantalum, titanium nitride, tantalum nitride, titanium-tungsten, tungsten nitride, tungsten-titanium nitride, zirconium nitride and titanium oxynitride, and said bottom electrode contains metal.

8. The semiconductor device according to claim 6, wherein said conductive film includes a barrier metal layer disposed in contact with said bottom electrode and having a portion formed to fill said hole.

9. The semiconductor device according to claim 6, wherein a portion of said conductive film contacting said bottom electrode has an uneven geometry.

10. The semiconductor device according to claim 6, wherein said conductive film has a recess having an opening in a plane contacting with said bottom electrode and said bottom electrode is formed to fill said recess.

11. A semiconductor device comprising:
a semiconductor substrate having a main surface;
an interlayer insulation film disposed on said main surface of said semiconductor substrate and having a top surface and first and second holes reaching said semiconductor substrate;
first and second conductive films filling said first and second holes, respectively;
first and second bottom electrodes extending away from said top surface of said interlayer insulation film, each having a portion with a top surface, and disposed in contact with said first and second conductive films, respectively;
an insulator disposed at said portion adjacent to the top surfaces of said first and second bottom electrodes and having one end connected to said first bottom electrode and the other end connected to said second bottom electrode;
a dielectric film disposed on said first and second bottom electrodes and;
a top electrode disposed on said dielectric film.

12. The semiconductor device according to claim 11, wherein said insulator has a top surface and said top surface of said insulator and said top surface of said first and second bottom electrodes are substantially in a single plane.
